(19) United States
(12) Patent Application Publication
(10) Pub. No.: US 2022/0307927 A1
(43) Pub. Date: Sep. 29, 2022

(54) FORCE SENSOR

(71) Applicant: Alps Alpine Co., Ltd., Tokyo (JP)

(72) Inventors: Hisanobu Okawa, Miyagi-ken (JP); Eiji Umetsu, Miyagi-ken (JP); Manabu Usui, Miyagi-ken (JP); Ayako Otsuka, Miyagi-ken (JP); Yuki Imai, Miyagi-ken (JP)

(21) Appl. No.: 17/841,891

(22) Filed: Jun. 16, 2022

Related U.S. Application Data
(63) Continuation of application No. PCT/JP2020/045846, filed on Dec. 9, 2020.

(30) Foreign Application Priority Data
Dec. 20, 2019 (JP) 2019-230804

(51) Int. Cl. G01L 1/18; H01L 41/113; H01L 41/053

(52) U.S. Cl. CPC G01L 1/18; H01L 41/1132; H01L 41/0533

(57) ABSTRACT

A force sensor includes a pressure-receiving member; a sensor substrate including a displaceable portion to be displaced under a load received by the pressure-receiving member, and piezoelectric resistors configured to electrically detect an amount of displacement of the displaceable portion; a base substrate having a sensor-mounting surface, and including electrical wiring portions electrically connected to the piezoelectric resistors; and a package substrate having a substrate-mounting surface and a pad surface provided with pad electrodes. The pressure-receiving member, the sensor substrate, and the base substrate are stacked in a normal direction to the substrate-mounting surface. When seen in the normal direction, an entirety of the displaceable portion is located within the pressure-receiving member. The pad surface is provided with, when seen in the normal direction, a fixing terminal at least a part of which overlaps at least a part of a first area that coincides with the pressure-receiving member.

### CLAIM OF PRIORITY

This application is a Continuation of International Application No. PCT/JP2020/045846 filed on Dec. 9, 2020, which claims benefit of priority to Japanese Patent Application No. 2019-230804 filed on Dec. 20, 2019. The entire contents of each application noted above are hereby incorporated by reference.

### BACKGROUND

### 1. Field of the Disclosure

The present disclosure relates to a force sensor and more specifically to a small force sensor configured to detect a load.

### 2. Description of the Related Art

In recent years, force sensors configured to detect a load have been employed in many electronic apparatuses and the like. International Publication No. WO2011/096093 discloses an input device that is effective in terms of thickness reduction, exhibits excellent stability in capacitance change in response to bending of a substrate, and a capacitance change with respect to the magnitude of the force to be applied to a movable electrode can be easily adjusted.

International Publication No. WO2015/199228 relates to a force detector configured to output a signal corresponding to the magnitude of a force applied thereto. Specifically, the force detector disclosed has a reduced size while being configured not to cause short circuit between electrodes. In Japanese Patent No. 5357100 discloses a force sensor package that includes a sensor substrate and a base substrate. The sensor substrate is configured to be displaced when receiving a load through a pressure-receiving member projecting from a surface thereof. The sensor substrate is provided with a plurality of piezoelectric resistors configured to electrically detect the amount of displacement of the sensor substrate. The base substrate is provided with electrical wiring portions electrically connected to the plurality of piezoelectric resistors.

With increasing demand for smaller force sensors, the sizes of sensors have been reduced, which have reduced the sizes of displaceable portions. However, if the size of a pressure-receiving member that receives a load is reduced in correspondence with the size of the displaceable portion, the pressure-receiving member tends to be damaged easily under the load, that is, the load-carrying capacity may be reduced. Moreover, if the pressure-receiving member receives a heavy load, other elements of the sensor, including the sensor substrate and the base substrate, may also be damaged.

### SUMMARY

The present invention provides a force sensor having a load-carrying capacity that is less likely to be reduced even if the size of a displaceable portion is reduced.

A force sensor configured to measure a load includes a pressure-receiving member configured to receive the load; a sensor substrate including a displaceable portion to be displaced under the load received by the pressure-receiving member. A plurality of piezoelectric resistors are configured to electrically detect an amount of displacement of the displaceable portion. A base substrate has a sensor-mounting surface on which the sensor substrate is mounted. The base substrate includes electrical wiring portions electrically connected to the plurality of piezoelectric resistors. A package substrate has a substrate-mounting surface on which the base substrate is mounted, and a pad surface located opposite the substrate-mounting surface. The pad surface is provided with pad electrodes through which electrical continuity with an external device is obtained. The pressure-receiving member, the sensor substrate, and the base substrate are stacked in a normal direction with respect to the substrate-mounting surface. When seen in the normal direction, an entirety of the displaceable portion is located within the pressure-receiving member. The pad surface of the package substrate is provided with, when seen in the normal direction, a fixing terminal at least a part of which overlaps at least a part of a first area that coincides with the pressure-receiving member.

### BRIEF DESCRIPTION OF THE DRAWINGS

FIGS. 1A and 1B illustrate a configuration of a force sensor according to an embodiment;

FIGS. 2A and 2B schematically illustrate the force sensor according to the embodiment;

FIGS. 3A and 3B illustrate a force sensor according to a first example;

FIGS. 4A to 4C illustrate the result of a stress simulation conducted on the force sensor according to the first example;

FIGS. 5A and 5B illustrate a force sensor according to a second example;

FIGS. 6A to 6C illustrate the result of a stress simulation conducted on the force sensor according to the second example;

FIGS. 7A and 7B illustrate a force sensor according to a third example;

FIGS. 8A to 8C illustrate the result of a stress simulation conducted on the force sensor according to the third example;

FIGS. 9A and 9B illustrate a force sensor according to a comparative example;

FIGS. 10A to 10C illustrate the result of a stress simulation conducted on the force sensor according to the comparative example;

FIG. 11 is a graph illustrating the stress generated in a displaceable portion with respect to the Y direction;

FIGS. 12A and 12B are enlargements of FIG. 11 for areas L1 and R1, respectively;

FIG. 13 is a graph illustrating the stress generated in the displaceable portion with respect to the X direction;

FIGS. 14A and B are enlargements of FIG. 13 for areas L2 and R2, respectively; and

FIGS. 15A to 15C schematically illustrate respective ways of bending caused by a load.

### DESCRIPTION OF THE EXEMPLARY EMBODIMENTS

An embodiment of the present invention will now be described in detail with reference to the accompanying drawings. In the following description, the same elements are denoted by the same reference signs, respectively, and redundant description of such elements is omitted accordingly.

With the configuration for the sensor disclosed below, the entirety of the displaceable portion is located within the pressure-receiving member. Therefore, even if an excessive force is applied to the pressure-receiving member, the force is prevented from being directly transmitted to a part of the displaceable portion to excessively bend the displaceable portion. Therefore, the displaceable portion is less likely to be damaged. Instead, in the case where the entirety of the displaceable portion is located within the pressure-receiving member, the sensitivity of the piezoelectric resistors is reduced because the bearing stress applied to the displaceable portion is smaller than in a case where the entirety of the pressure-receiving member is located within the displaceable portion. Therefore, the sensor substrate including the displaceable portion needs to be deformable appropriately under the pressure transmitted from the pressure-receiving member.

Accordingly, in the case where the entirety of the displaceable portion is located within the pressure-receiving member when seen in the normal direction with respect to the substrate-mounting surface, it is important from the viewpoint of increasing the sensitivity of the piezoelectric resistors that, in the normal direction, at least a part of the fixing terminal overlaps at least a part of the first area that coincides with the pressure-receiving member. In such a configuration, the pressure transmitted from the pressure-receiving member is less likely to bend the base substrate. In contrast, if the fixing terminal is not provided appropriately, the pressure transmitted from the pressure-receiving member is dispersed over the entirety of the sensor substrate and causes the base substrate connected to the sensor substrate to bend. Consequently, the pressure transmitted from the pressure-receiving member is less likely to be reflected as a change in the stress generated in the displaceable portion of the sensor substrate, leading to a reduction in the sensitivity of the piezoelectric resistors.

### Configuration of Force Sensor

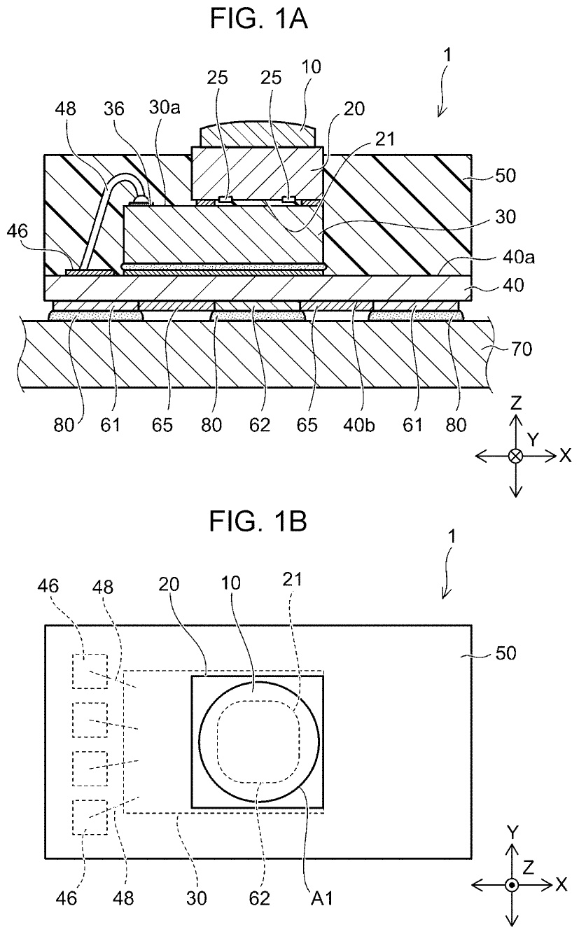

FIGS. 1A and 1B illustrate a configuration of a force sensor 1 according to the present embodiment. FIG. 1A is a sectional view. FIG. 1B is a plan view.

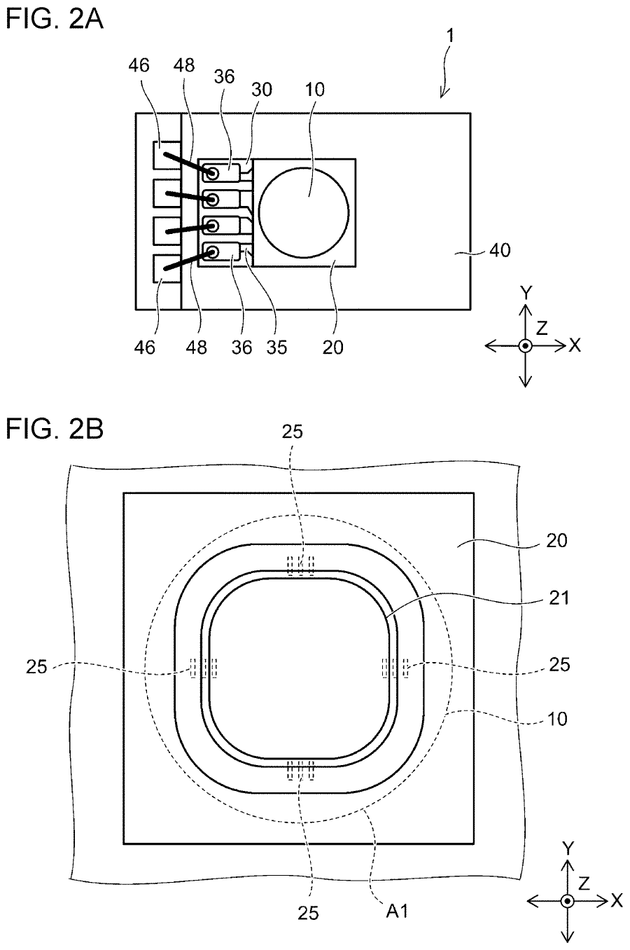

FIGS. 2A and 2B schematically illustrate the force sensor 1 according to the present embodiment. FIG. 2A is a plan view, with sealing resin 50 removed. FIG. 2B is a plan view of a displaceable portion 21. In the description of the embodiment, the normal direction with respect to a substrate-mounting surface 40a is defined as the Z direction. Furthermore, one of directions that are orthogonal to the normal direction (Z direction) is defined as the X direction, and another is defined as the Y direction.

The force sensor 1 according to the present embodiment is configured to measure a load and includes a pressure-receiving member 10, a sensor substrate 20, a base substrate 30, and a package substrate 40. The pressure-receiving member 10 projects in, for example, a round columnar shape from the upper surface of the sealing resin 50, which serves as a package. The pressure-receiving member 10 receives a load to be applied thereto from the outside. The pressure-receiving member 10 is formed from a silicon compound or silicon (the same material as for the sensor substrate 20).

The sensor substrate 20 includes the displaceable portion 21 and a plurality of piezoelectric resistors 25. The displaceable portion 21 is to be displaced under the load received by the pressure-receiving member 10 and is located on a face of the sensor substrate 20 that is opposite the face on which the pressure-receiving member 10 is provided. The piezoelectric resistors 25 are configured to electrically detect the amount of displacement of the displaceable portion 21. The plurality of piezoelectric resistors 25 are arranged at the periphery of the displaceable portion 21 in such a manner as to be 90° apart from one another. When the displaceable portion 21 is displaced under a load received by the pressure-receiving member 10, the electrical resistances of the plurality of piezoelectric resistors 25 change in correspondence with the amount of displacement. Such a change changes the potential at the midpoint of a bridge circuit, which is formed of the plurality of piezoelectric resistors 25. The changed midpoint potential is outputted as a sensor output to a known measuring device.

The base substrate 30 has a sensor-mounting surface 30a, on which the sensor substrate 20 is mounted. The base substrate 30 includes electrical wiring portions 35, which are electrically connected to the plurality of piezoelectric resistors 25, respectively. The base substrate 30 is provided on an extended portion of the sensor-mounting surface 30a thereof with first pads 36, which are electrically continuous with the electrical wiring portions 35.

The package substrate 40 has the substrate-mounting surface 40a and a pad surface 40b. The base substrate 30 is mounted on the substrate-mounting surface 40a. The pad surface 40b is located opposite the substrate-mounting surface 40a. The package substrate 40 is provided on an extended portion of the substrate-mounting surface 40a thereof with second pads 46. The second pads 46 and the first pads 36 are connected to each other with bonding wires 48.

The pad surface 40b of the package substrate 40 is provided with a plurality of electrode terminals 61, through which electrical continuity with an external device is obtained. The plurality of electrode terminals 61 are electrically continuous with the plurality of piezoelectric resistors 25 through the bonding wires 48 and the electrical wiring portions 35. If four electrode terminals 61 are provided in correspondence with four piezoelectric resistors 25, the electrode terminals 61 are positioned at the four respective corners of the pad surface 40d of the package substrate 40. The electrode terminals 61 are soldered to a connection pattern (not illustrated) provided on a mounting substrate 70, on which the force sensor 1 is mounted.

The sealing resin 50 is provided over the substrate-mounting surface 40a of the package substrate 40. The sealing resin 50 covers the base substrate 30, the bonding wires 48, and the sensor substrate 20, thereby serving as a package.

In the force sensor 1 configured as above, the pressure-receiving member 10, the sensor substrate 20, and the base substrate 30 are stacked in the normal direction (Z direction) with respect to the substrate-mounting surface 40a. When seen in the normal direction (Z direction), the entirety of the displaceable portion 21 is located within the pressure-receiving member 10. The pad surface 40b of the package substrate 40 is provided with a fixing terminal 62. When seen in the normal direction (Z direction), at least a part of the fixing terminal 62 overlaps at least a part of a first area A1, the first area A1 coinciding with the pressure-receiving member 10. The fixing terminal 62 may be electrically independent of the plurality of electrode terminals 61 or may be electrically continuous with any one of the plurality of electrode terminals 61.

When the force sensor 1 according to the present embodiment is seen in the normal direction (Z direction), the entirety of the displaceable portion 21 is located within the pressure-receiving member 10. Therefore, it is less likely that the pressure-receiving member 10 seen in the normal direction (Z direction) has so small an area as to be damaged when receiving a load. It is also less likely that the pressure-receiving member 10 under a load locally pushes the sensor substrate 20 to damage the sensor substrate 20. That is, the force sensor 1 according to the present embodiment has an excellent load-carrying capacity.

In the force sensor 1 according to the present embodiment, a load received by the pressure-receiving member 10 causes the sensor substrate 20 to bend, which changes the relative position between the displaceable portion 21 and portions of the sensor substrate 20 where the piezoelectric resistors 25 are provided, and the change is detected as the displacement of the displaceable portion 21 by the piezoelectric resistors 25. Therefore, if the base substrate 30 and the package substrate 40 have easily bendable structures, the load applied to the pressure-receiving member 10 does not appropriately bend the sensor substrate 20 and is propagated as a displacement of the base substrate 30. Consequently, the load received by the pressure-receiving member 10 cannot be detected appropriately. Hence, in the force sensor 1 according to the present embodiment, at least a part of the fixing terminal 62 overlaps at least a part of the first area A1. In such a configuration, the load received by the pressure-receiving member 10 is less likely to escape to the base substrate 30 and the package substrate 40. Accordingly, the load received by the pressure-receiving member 10 is appropriately transmitted to the sensor substrate 20 and causes the sensor substrate 20 to bend to an appropriate extent. Thus, the force sensor 1 according to the present embodiment assuredly exerts an appropriate detection sensitivity through the piezoelectric resistors 25.

It is preferable that the fixing terminal 62 be formed from a metal material that is applicable to solder connection. In such a case, the fixing terminal 62, which supports the displaceable portion 21, is allowed to be connected to the package substrate 40 with solder 80. The solder connection for the fixing terminal 62 may be performed in the process of solder connection between the electrode terminals 61 and the package substrate 40. Between each adjacent two of the electrode terminals 61 and between the fixing terminal 62 and the electrode terminals 61 is provided a layer 65, which is formed by printing with a solder-repellent material. With the presence of the layer 65, unintentional short circuit is less likely to occur between each adjacent two of the electrode terminals 61 and between the fixing terminal 62 and the electrode terminals 61 during the process of solder connection. The electrode terminals 61 and the fixing terminal 62 may be formed by printing with an electrically conductive material.

### Results of Stress Distribution Simulations

Results of stress distribution simulations for the force sensor 1 according to the present embodiment will now be described.

### First Example

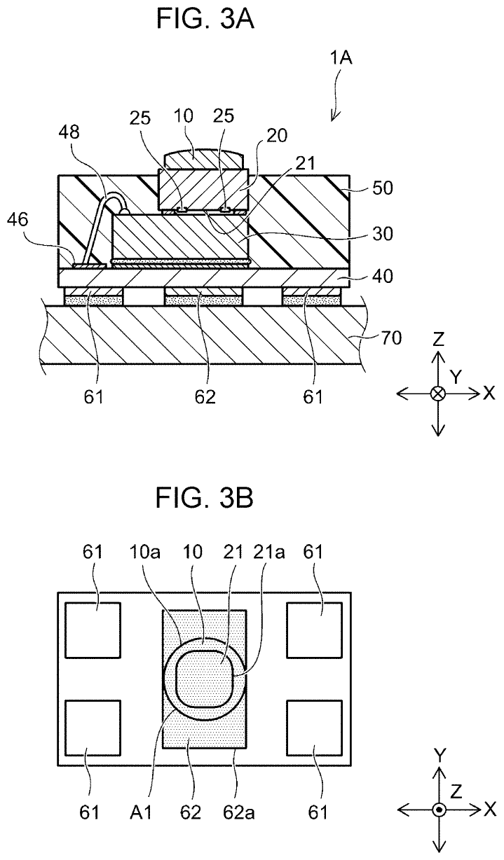

FIGS. 3A and 3B illustrate a force sensor 1A according to a first example. FIG. 3A is a schematic sectional view of the force sensor 1A according to the first example. FIG. 3B is a schematic plan view of the force sensor 1A, illustrating the positional relationship of a pressure-receiving member 10, a displaceable portion 21, and a fixing terminal 62 thereof. As a matter of convenience of description, the fixing terminal 62 is shaded.

In the force sensor 1A according to the first example, the entirety of the displaceable portion 21 is located within the fixing terminal 62. Specifically, when seen in the normal direction (Z direction), the fixing terminal 62 is positioned in such a manner as to have the entirety of the pressure-receiving member 10 therewithin. In other words, when seen in the normal direction (Z direction), the entirety of the pressure-receiving member 10 is located within the fixing terminal 62, and the entirety of the displaceable portion 21 is located within the pressure-receiving member 10.

In the force sensor 1A, the X-direction length of the fixing terminal 62 is substantially equal to the X-direction length of the pressure-receiving member 10, and the Y-direction length of the fixing terminal 62 is greater than the Y-direction length of the pressure-receiving member 10.

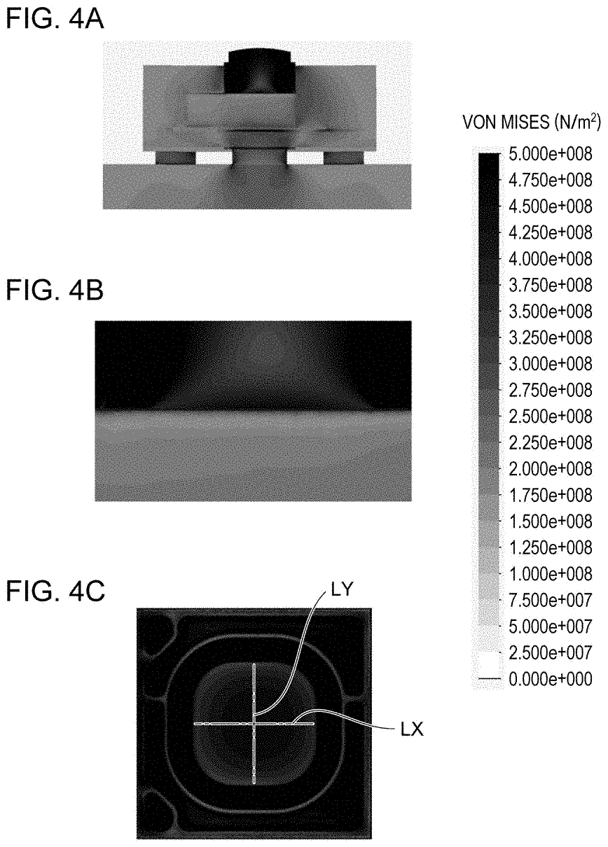

FIGS. 4A to 4C illustrate the result of a stress simulation conducted on the force sensor 1A according to the first example. In the stress simulation, the distribution of stress under a force of 10 newtons (N) applied to the pressure-receiving member 10 was calculated. FIG. 4A illustrates a stress distribution over the entirety of the force sensor 1A. FIG. 4B illustrates a stress distribution at the boundary between the pressure-receiving member 10 and the sensor substrate 20. FIG. 4C illustrates a stress distribution in the plane of the displaceable portion 21.

### Second Example

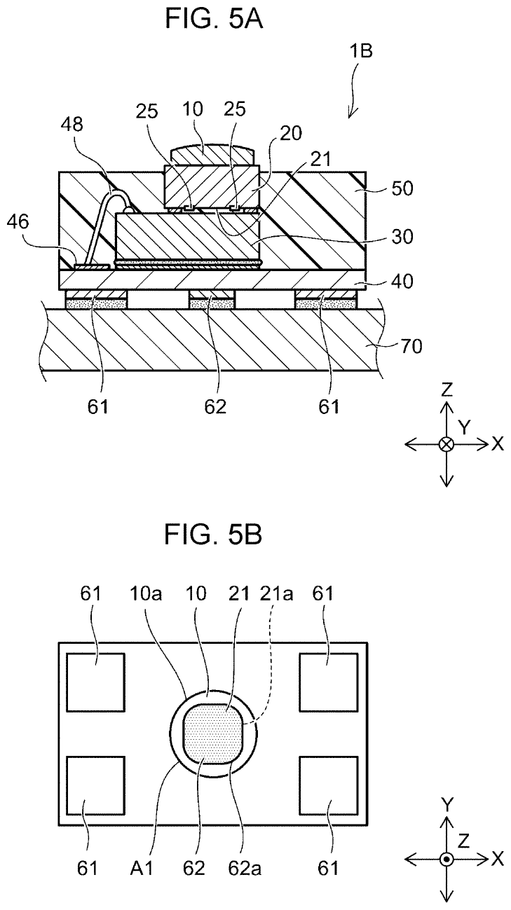

FIGS. 5A and 5B illustrate a force sensor 1B according to a second example. FIG. 5A is a schematic sectional view of the force sensor 1B according to the second example. FIG. 5B is a schematic plan view of the force sensor 1B, illustrating the positional relationship of a pressure-receiving member 10, a displaceable portion 21, and a fixing terminal 62 thereof. As a matter of convenience of description, the fixing terminal 62 is shaded.

In the force sensor 1B according to the second example, when seen in the normal direction (Z direction), the displaceable portion 21 and the fixing terminal 62 are of a substantially equal size and are arranged in such a manner as to coincide with each other.

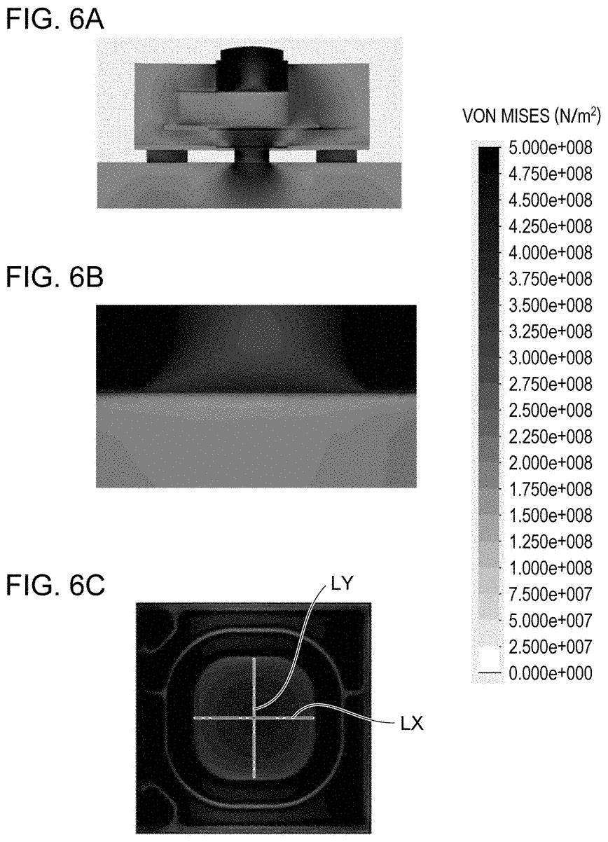

FIGS. 6A to 6C illustrate the result of a stress simulation conducted on the force sensor 1B according to the second example. In the stress simulation, the distribution of stress under a force of 10 newtons (N) applied to the pressure-receiving member 10 was calculated. FIG. 6A illustrates a stress distribution over the entirety of the force sensor 1B. FIG. 6B illustrates a stress distribution at the boundary between the pressure-receiving member 10 and the sensor substrate 20. FIG. 6C illustrates a stress distribution in the plane of the displaceable portion 21.

### Third Example

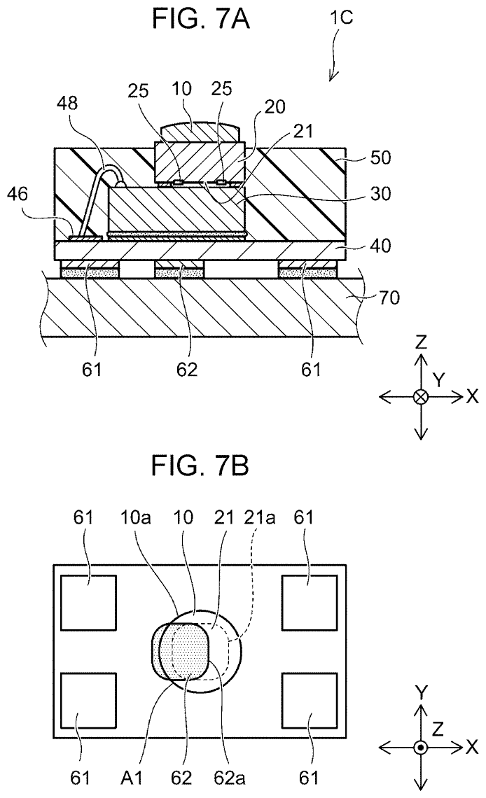

FIGS. 7A and 7B illustrate a force sensor 1C according to a third example. FIG. 7A is a schematic sectional view of the force sensor 1C according to the third example. FIG. 7B is a schematic plan view of the force sensor 1C, illustrating the positional relationship of a pressure-receiving member 10, a displaceable portion 21, and a fixing terminal 62 thereof. As a matter of convenience of description, the fixing terminal 62 is shaded.

In the force sensor 1C according to the third example, when seen in the normal direction (Z direction), the displaceable portion 21 and the fixing terminal 62 are of a substantially equal size but are arranged such that a part of each of the two overlap a part of the other. The fixing terminal 62 of the force sensor 1C according to the third example is offset with respect to the displaceable portion 21 in the X direction in such a manner as to intersect a perimeter 21a of the displaceable portion 21 and a perimeter 10a of the pressure-receiving member 10.

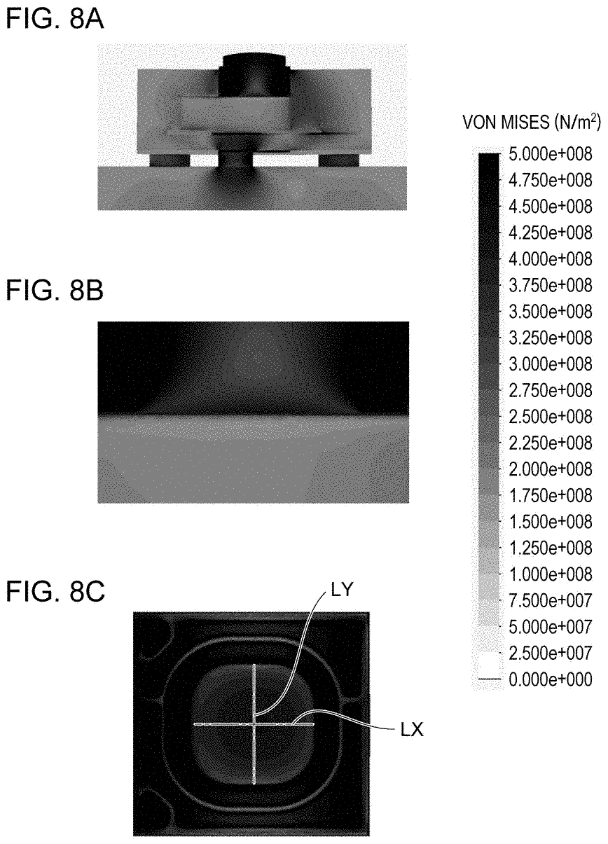

FIGS. 8A to 8C illustrate the result of a stress simulation conducted on the force sensor 1C according to the third example. In the stress simulation, the distribution of stress under a force of 10 newtons (N) applied to the pressure-receiving member 10 was calculated. FIG. 8A illustrates a stress distribution over the entirety of the force sensor 1C. FIG. 8B illustrates a stress distribution at the boundary between the pressure-receiving member 10 and the sensor substrate 20. FIG. 8C illustrates a stress distribution in the plane of the displaceable portion 21.

### COMPARATIVE EXAMPLE

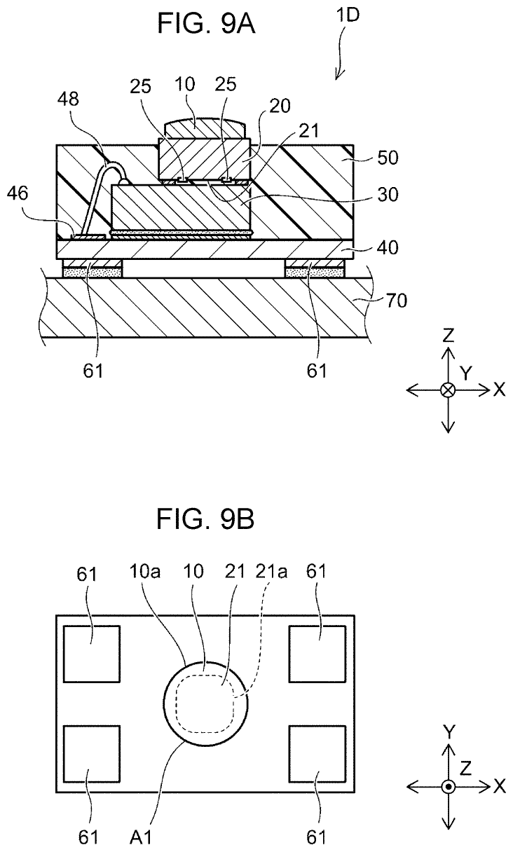

FIGS. 9A and 9B illustrate a force sensor 1D according to a comparative example. FIG. 9A is a schematic sectional view of the force sensor 1D according to the comparative example. FIG. 9B is a schematic plan view of the force sensor 1D, illustrating the positional relationship of a pressure-receiving member 10 and a displaceable portion 21 thereof.

The force sensor 1D according to the comparative example includes no fixing terminal 62. Specifically, when seen in the normal direction (Z direction), the force sensor 1D includes no element at a location coinciding with the pressure-receiving member 10 and the displaceable portion 21.

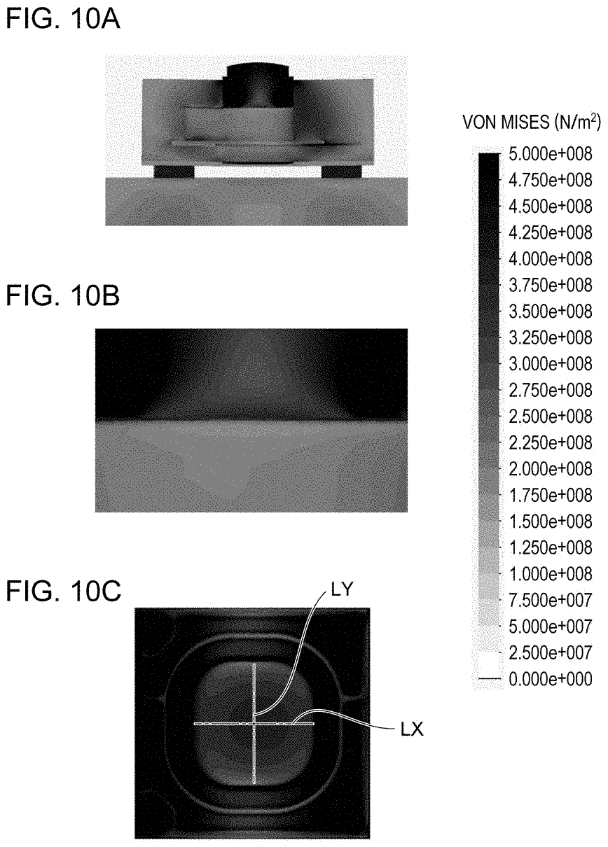

FIGS. 10A to 10C illustrate the result of a stress simulation conducted on the force sensor 1D according to the comparative example. In the stress simulation, the distribution of stress under a force of 10 newtons (N) applied to the pressure-receiving member 10 was calculated. FIG. 10A illustrates a stress distribution over the entirety of the force sensor 1D. FIG. 10B illustrates a stress distribution at the boundary between the pressure-receiving member 10 and the sensor substrate 20. FIG. 10C illustrates a stress distribution in the plane of the displaceable portion 21.

### Stress Variation Among Examples

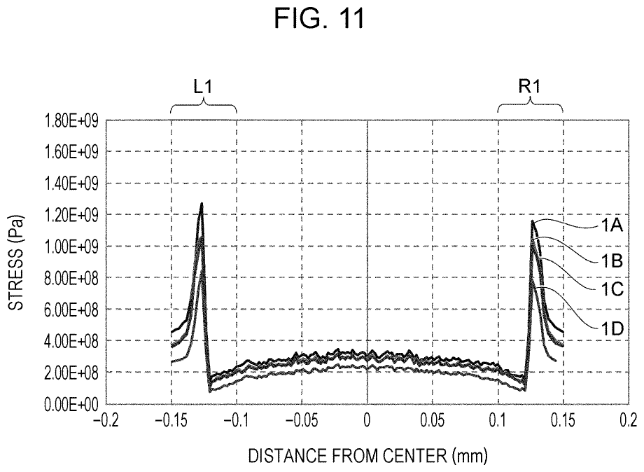

FIG. 11 is a graph illustrating the stress generated in the displaceable portion 21 with respect to the Y direction. Specifically, FIG. 11 graphically illustrates the stress generated in the individual examples on a line LY, which is illustrated in FIGS. 4C, 6C, 8C, and 10C and extends in the Y direction while passing through the center of the displaceable portion 21.

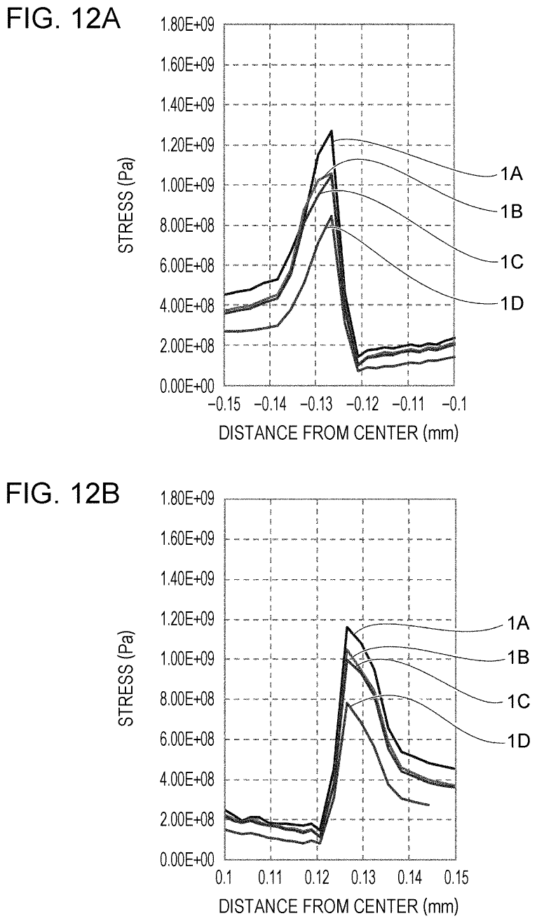

FIG. 12A is an enlargement of FIG. 11 for an area L1. FIG. 12B is an enlargement of FIG. 11 for an area R1. The Y-direction positions taken in FIGS. 12A and 12B correspond to respective areas at the perimeter 21a of the displaceable portion 21 on the line LY.

As illustrated in the graphs in FIGS. 11, 12A, and 12B, the stress generated in the displaceable portion 21 on the line LY was greatest in the force sensor 1A according to the first example, and second greatest in the force sensor 1B according to the second example and the force sensor 1C according to the third example both at about the same magnitude. The stress was smallest in the force sensor 1D according to the comparative example. Such a result is considered to be brought by differences in the effect of the presence/absence of the fixing terminal 62.

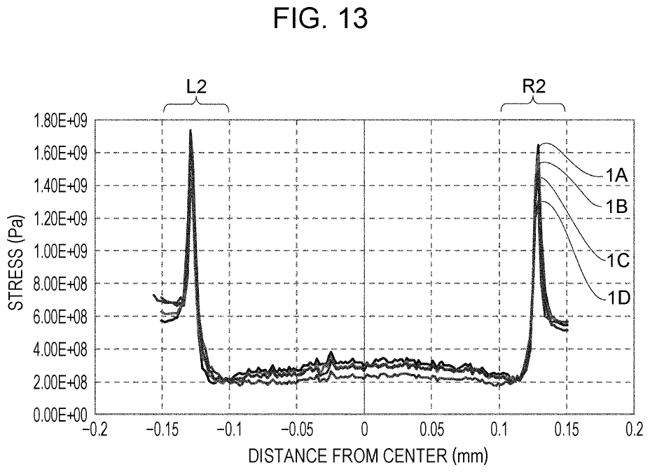

FIG. 13 is a graph illustrating the stress generated in the displaceable portion 21 with respect to the X direction. Specifically, FIG. 13 graphically illustrates the stress generated in the individual examples on a line LX, which is illustrated in FIGS. 4C, 6C, 8C, and 10C and extends in the X direction while passing through the center of the displaceable portion 21.

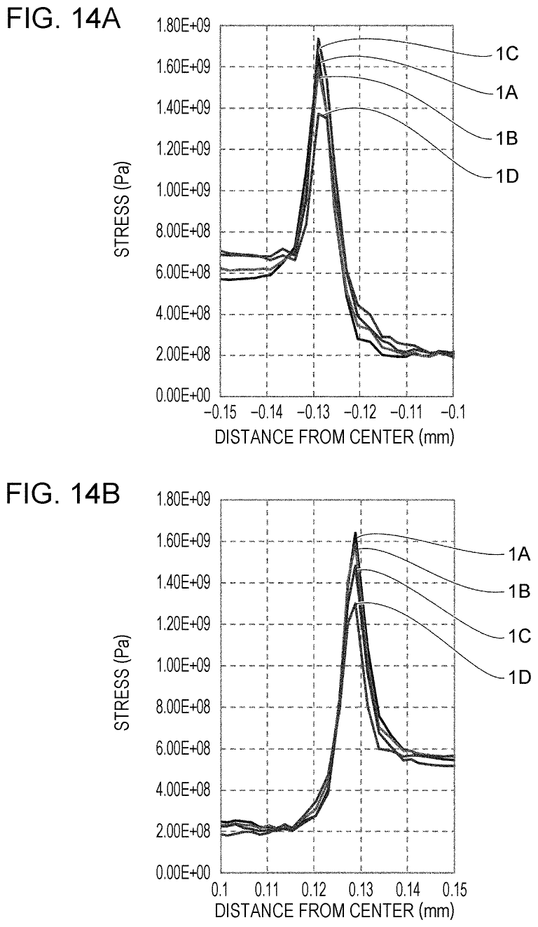

FIG. 14A is an enlargement of FIG. 13 for an area L2. FIG. 14B is an enlargement of FIG. 13 for an area R2. The X-direction positions taken in FIGS. 14A and 14B correspond to respective areas at the perimeter 21a of the displaceable portion 21 on the line LX.

As illustrated in the graphs in FIGS. 13, 14A, and 14B, regarding the stress generated in the displaceable portion 21 on the line LX, the stress in a central area of the displaceable portion 21 was greatest in the force sensor 1A according to the first example, and second greatest in the force sensor 1B according to the second example and the force sensor 1C according to the third example both at about the same magnitude. The stress was smallest in the force sensor 1D according to the comparative example. Such a result is also considered to be brought by differences in the effect of the presence/absence of the fixing terminal 62.

Regarding the stress generated in the displaceable portion 21 on the line LX, particularly at the perimeter 21a of the displaceable portion 21, the stress in the area L2 was greatest in the force sensor 1C according to the third example, and second greatest in the force sensor 1A according to the first example and the force sensor 1B according to the second example both at about the same magnitude. The stress was smallest in the force sensor 1D according to the comparative example.

Such a result is considered to be brought by the following. In the force sensor 1C according to the third example, the fixing terminal 62 is offset toward the area L2 such that a part of the fixing terminal 62 overlaps the perimeter 21a of the displaceable portion 21 and the perimeter 10a of the pressure-receiving member 10. Therefore, little escape was provided for the stress in the area L2. Accordingly, a satisfactory stress was applied to the displaceable portion 21.

Regarding the stress generated in the displaceable portion 21 on the line LX, the stress in the area R2 was greatest in the force sensor 1A according to the first example, second greatest in the force sensor 1B according to the second example, and third greatest in the force sensor 1C according to the third example. The stress was smallest in the force sensor 1D according to the comparative example.

Such a result is considered to be related to the position of the fixing terminal 62 in the area R2. Specifically, focusing on the area R2, the fixing terminal 62 of the force sensor 1A according to the first example overlaps the perimeter 21a of the displaceable portion 21 and the perimeter 10a of the pressure-receiving member 10, the fixing terminal 62 of the force sensor 1B according to the second example overlaps the perimeter 21a of the displaceable portion 21, and the fixing terminal 62 of the force sensor 1C according to the third example overlaps neither the perimeter 21a of the displaceable portion 21 nor the perimeter 10a of the pressure-receiving member 10. That is, the stress generated in the area R2 varies in correspondence with the degree of overlap of the fixing terminal 62 with the perimeter 21a of the displaceable portion 21 and the perimeter 10a of the pressure-receiving member 10.

The above results of the simulations indicate the following. It is preferable that when seen in the normal direction (Z direction), the entirety of the displaceable portion 21 be located within the fixing terminal 62. This is because the pressure transmitted from the pressure-receiving member 10 is borne by the fixing terminal 62 over an area wider than the displaceable portion 21, whereby the displaceable portion 21 is prevented from bending excessively.

It is also preferable that when seen in the Z direction, the perimeter 21a of the displaceable portion 21 and the perimeter, 62a, of the fixing terminal 62 overlap each other. This is because the pressure transmitted from the pressure-receiving member 10 is borne by the fixing terminal 62, whereby the displaceable portion 21 is prevented from bending excessively. Furthermore, the stress generated in response to such a load is efficiently transmitted to the perimeter 21a of the displaceable portion 21.

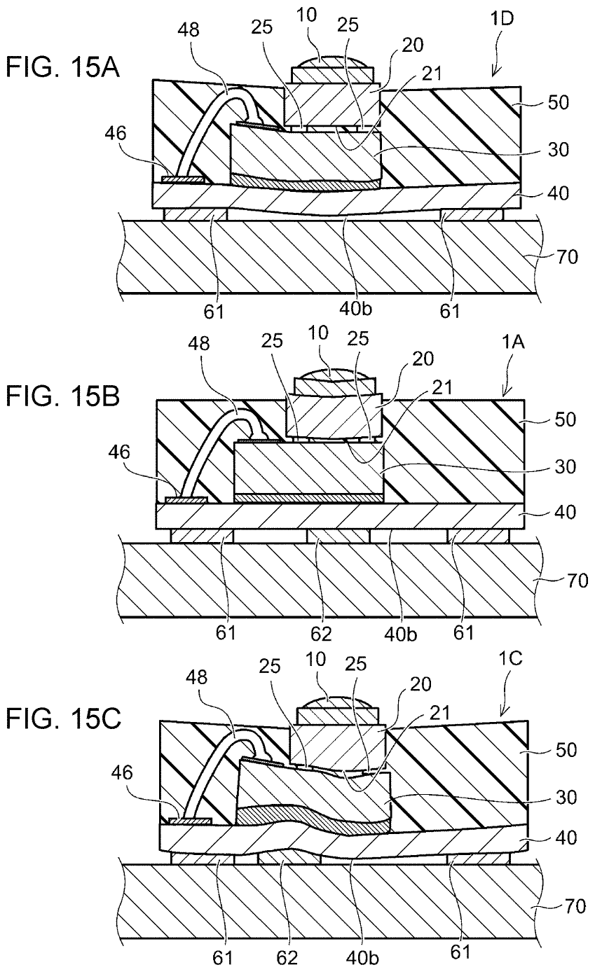

FIGS. 15A to 15C schematically illustrate respective ways of bending under a load. FIG. 15A illustrates how the force sensor 1D according to the comparative example bends. FIG. 15B illustrates how the force sensor 1A according to the first example bends. FIG. 15C illustrates how the force sensor 1C according to the third example bends. In FIGS. 15A to 15C, the state of bending under the load applied to the pressure-receiving member 10 is exaggerated.

In the force sensor 1D according to the comparative example illustrated in FIG. 15A, no fixing terminal 62 is present on the pad surface 40b of the package substrate 40 at a location coinciding with the pressure-receiving member 10 and the displaceable portion 21. Therefore, when a load is received by the pressure-receiving member 10, a region of the force sensor 1D that is below the pressure-receiving member 10 is pushed downward, whereby the base substrate 30 and the package substrate 40 bend significantly, meanwhile the sensor substrate 20 does not bend. Therefore, the load received by the pressure-receiving member 10 cannot appropriately be detected by the piezoelectric resistors 25.

In contrast, in the force sensor 1A according to the first example illustrated in FIG. 15B, the fixing terminal 62 is present on the pad surface 40b of the package substrate 40 at a location coinciding with the pressure-receiving member 10 and the displaceable portion 21. Therefore, the load received by the pressure-receiving member 10 is borne by the fixing terminal 62. Hence, in a region of the force sensor 1A that is below the pressure-receiving member 10, the base substrate 30 and the package substrate 40 are less likely to bend. Accordingly, the load received by the pressure-receiving member 10 is effectively transmitted to the sensor substrate 20, whereby a relative displacement of the displaceable portion 21 that is caused by the bending of the sensor substrate 20 is efficiently detected as a change in the resistances of the piezoelectric resistors 25.

In the force sensor 1C according to the third example illustrated in FIG. 15C, the fixing terminal 62 is present as with the case of the force sensor 1A according to the first example but is shifted with respect to the location coinciding with the pressure-receiving member 10 and the displaceable portion 21. In such a case, the load received by the pressure-receiving member 10 is borne by the fixing terminal 62. Since the fixing terminal 62 is present at the shifted position, the force sensor 1C tends to bend far more easily in a region where the distance between the fixing terminal 62 and the electrode terminals 61 is relatively long than in a region where the foregoing distance is relatively short. Accordingly, it is preferable that at least a part of the fixing terminal 62 overlap at least a part of the area (first area A1) that coincides with the pressure-receiving member 10. It is more preferable that the fixing terminal 62 overlap the entirety of the area (first area A1) that coincides with the pressure-receiving member 10.

To summarize, according to the present embodiment, since the fixing terminal 62 is provided, excessive bending of the displaceable portion 21 is less likely to occur. Such a configuration provides the force sensor 1 with detection sensitivity that is less likely to be reduced and with an increased load-carrying capacity.

While an embodiment has been described above, the present invention is not limited thereto. For example, any addition, deletion, and design changes of relevant elements that are made to the above embodiment and any combinations of relevant features of the above embodiment that are conceived by those skilled in the art are within the scope of the present invention, as long as such embodiments include the essence of the present invention.

What is claimed is:

1. A force sensor comprising:
a pressure-receiving member that receives a load;
a sensor substrate including a displaceable portion to be displaced under the load received by the pressure-receiving member, and a plurality of piezoelectric resistors that electrically detect an amount of displacement of the displaceable portion;
a base substrate having a sensor-mounting surface on which the sensor substrate is mounted, the base substrate including electrical wiring portions electrically connected to the plurality of piezoelectric resistors; and
a package substrate having a substrate-mounting surface on which the base substrate is mounted, and a pad surface located opposite the substrate-mounting surface, the pad surface having pad electrodes through to electrically connect to an external device,
wherein the pressure-receiving member, the sensor substrate, and the base substrate are stacked in a normal direction with respect to the substrate-mounting surface,
wherein when seen in the normal direction, an entirety of the displaceable portion is located within the pressure-receiving member, and
wherein the pad surface of the package substrate has, when seen in the normal direction, a fixing terminal at least a part of which overlaps at least a part of a first area that coincides with the pressure-receiving member.

2. The force sensor according to claim 1, wherein when seen in the normal direction, the entirety of the displaceable portion is located within the fixing terminal.

3. The force sensor according to claim 1, wherein when seen in the normal direction, a perimeter of the displaceable portion and a perimeter of the fixing terminal overlap each other.

4. The force sensor according to claim 1, wherein when seen in the normal direction, a perimeter of the pressure-receiving member and a perimeter of the fixing terminal overlap each other.

5. The force sensor according to claim 1, wherein the fixing terminal is comprised of a metal material that is solderable.

6. A force sensor comprising:
a pressure-receiving member that receives a load;
a sensor substrate including a displaceable portion that is displaced by the load received by the pressure-receiving member, and a plurality of piezoelectric resistors that detect an amount of displacement of the displaceable portion;
a base substrate having a surface on which the sensor substrate is mounted, the base substrate including electrical wiring portions electrically connected to the plurality of piezoelectric resistors; and
a package substrate having a surface on which the base substrate is mounted, and a pad surface located opposite the substrate surface, the pad surface having pad electrodes to electrical connect to an external device,
wherein the pressure-receiving member, the sensor substrate, and the base substrate are stacked in a normal direction with respect to the substrate surface,
wherein when seen in the normal direction, an entirety of the displaceable portion is located within the pressure-receiving member, and
wherein the pad surface of the package substrate has, when seen in the normal direction, a fixing terminal at least a part of which overlaps at least a part of a first area that coincides with the pressure-receiving member.
